(19) United States
(12) Patent Application Publication
(10) Pub. No.: US 2008/0028345 A1
(43) Pub. Date: Jan. 31, 2008

(54) APPARATUS AND METHOD FOR INTEGRATED CIRCUIT DESIGN FOR CIRCUIT EDIT

(75) Inventors: Hitesh Suri, San Jose, CA (US); Tahir Malik, Fremont, CA (US); Theodore R. Lundquist, Milpitas, CA (US)

Correspondence Address: SUGHRUE MION, PLLC, 401 Castro Street, Ste 220, Mountain View, CA, 94041-2007, US

(73) Assignee: Credence Systems Corporation, Milpitas, CA (US)

(21) Appl. No.: 11/869,336

(22) Filed: Oct. 9, 2007

Related U.S. Application Data
(63) Continuation-in-part of application No. 11/363,787, filed on Feb. 27, 2006.
(60) Provisional application No. 60/656,333, filed on Feb. 25, 2005.
(60) Provisional application No. 60/870,079, filed on Dec. 14, 2006.

(51) Int. Cl. G06F 17/50; H01L 29/00

(52) U.S. Cl. 716/2; 257/499; 257/E29.001

(57) ABSTRACT

A method and apparatus for optimizing an integrated circuit design for post-fabrication circuit editing and diagnostics. The method and apparatus is specifically directed to adding designed-for-edit modifications and designed-for-diagnostics structures to an integrated circuit design for post-fabrication circuit editing with a charged-particle beam tool. An integrated circuit design may be modified to create efficient and reliable access to specified nodes and structures, such as spare gates, by the charged-particle beam tool during subsequent testing and debugging of the fabricated device. Additionally, structures such as spare gates, spare transistors, spare metal wires, and debug circuitry may be added to an integrated circuit design to provide for easier editing of portions of the design that may fail.

### CROSS-REFERENCE TO RELATED APPLICATIONS

The present application claims priority to and is a continuation-in-part of application Ser. No. 11/363,787, titled “Apparatus and Method for Circuit Operation Definition,” filed on Feb. 27, 2006, which is a non-provisional application claiming priority to provisional application No. 60/656,333 titled “Apparatus and Method for Circuit Operation Definition,” filed on Feb. 27, 2005, which are hereby incorporated by reference herein. This application also claims priority from Provisional Application Ser. No. 60/870,079, filed on Dec. 14, 2006, the entire disclosure of which is incorporated herein by reference.

### FIELD OF THE INVENTION

Aspects of the present invention generally involve the field of integrated circuit design optimization for testing, characterization and/or modification to test design alterations, and more particularly involves an apparatus and method for optimizing the placement of circuit edit structures that may be accessed by a circuit operation tool, such as a focused ion beam tool, e-beam tool, laser tool, or the like.

### BACKGROUND

Fabrication of a newly-designed integrated circuit (“IC”) involves preparation of silicon substrate wafers, generation of masks, doping of the silicon substrate, deposition of metal layers, and so on. The IC typically has many physical layers on the substrate with various individual electronic components, such as resistors, capacitors, diodes, and transistors, collectively forming one or more electrical circuits. The metal layers, which may be aluminum, copper, or other conductive material, provide the interconnection mesh between the various individual electronic components to form integrated electrical circuits. Vias formed of electrically conductive material provide communication pathways between various metal layers. Contacts provide communication links between metal layers and individual electronic components embedded in the silicon substrate.

Unfortunately, a new IC of any complexity rarely works as expected when first fabricated. Normally, some defects in the operation of the IC are discovered during testing. Also, some functions of the IC may operate properly under limited conditions, but fail when operated across a full range of temperature and voltage in which the IC is expected to perform. Once the IC has been tested, the designer may change the design, initiate the manufacture of a second prototype IC via the lengthy process described above, and then test the new IC once again. However, no guarantee exists that the design changes will correct the problems previously encountered, or that all of the problems in the previous version of the IC have been discovered. It is also possible that a design will need to be altered for some other reason.

Charged particle beam systems such as focused ion beam (“FIB”) systems and electron beam (“e-beam”) systems, laser-based systems, and other integrated circuit operation platforms have found many applications in various areas of science and industry. Particularly in the semiconductor industry, charged particle beam systems are used for integrated circuit edits, probe point creation, failure analysis, and numerous other applications. More generally, servicing platforms may be used for testing, analyzing, editing, and/or repairing an IC. For example, charged particle beam systems may be used to edit a circuit (“circuit editing”) in order to test design changes and thereby avoid some or all of the expense and time of testing design changes through fabrication. Particularly, a FIB tool typically includes a particle beam production column designed to precisely focus an ion beam on the IC at the place intended for the desired intervention. Such a column typically comprises a source of ions, such as Ga+ (Gallium), produced from liquid metal. The Ga+ is used to form the ion beam, which is focused on the IC by a focusing device comprising a certain number of electrodes operating at determined potentials so as to form an electrostatic lens system. Other types of charged particle beam systems deploy other arrangements to produce charged particle beams capable of various types of circuit edits and operations generally. Further, laser-based systems deploy various types of lasers for purposes of laser-based circuit editing.

As mentioned above, IC manufacturers sometimes employ a FIB system to edit the prototype IC, thereby altering the connections and other electronic structures of the IC. Circuit editing involves employing an ion beam to remove and deposit material in an IC with precision. Removal of material, or milling, may be achieved through a process sometimes referred to as sputtering. Addition or deposition of material, such as a conductor, may be achieved through a process sometimes referred to as ion-induced deposition. Through removal and deposit of material, electrical connections may be severed or added, which allows designers to implement and test design modifications without repeating the wafer fabrication process.

Although the value of circuit editing is well-established, its benefits may not be fully realized because the IC design process may not adequately make provision for the circuit edit process. A FIB may be used to connect or disconnect circuit elements to correct logic faults or improve operational speed as long as the nodes and elements that need modification can be found and accessed. In advanced designs with nine or more metal layers between the front-side of the IC and the transistors, finding the areas of interest and gaining access to them may not be possible because other objects may block direct access to the area of interest. Access from the back-side may be difficult in the absence of good navigational features because the desired feature may not be visible and may also be hidden under multiple layers.

### SUMMARY

The following summary is provided in order to provide a basic understanding of some aspects and features of the invention. This summary is not an extensive overview of the invention, and as such it is not intended to particularly identify key or critical elements of the invention, or to delineate the scope of the invention. The sole purpose of this summary is to present some concepts of the invention in a simplified form as a prelude to the more detailed description that is presented below.

The present invention solves the aforementioned problems and meets the aforementioned needs by providing a method and apparatus for optimizing the design of an integrated circuit for post-fabrication circuit edit by implementing design modifications and adding structures that simplify the circuit edit process, particularly when using a charged-particle beam tool.

In one aspect of the present invention, a method for an integrated circuit design for circuit edit is provided, comprising: receiving access to computer aided design data for an integrated circuit; receiving an identification of at least one feature of interest in the computer aided design data for a circuit edit operation; and providing a layout modification to optimize the circuit edit operation, the layout modification associated with the computer aided design data. The method may further comprise selecting the feature of interest from the group consisting of a net, metal line, layer, contact, and via. The method may further comprise selecting the circuit edit operation from the group consisting of net cut, net join, probe point, and gate replacement. The operation of optimizing for circuit edit may comprise moving the feature of interest up at least one level. The operation of moving the feature of interest up at least one level may further comprise: querying a database to determine if there is an object above the feature of interest; and in the event there is no object above the feature of interest, moving the feature of interest up at least one level. The method may further comprise moving the feature of interest to the top level. The operation of optimizing for circuit edit may comprise moving the feature of interest down at least one level. The operation of moving the feature of interest down at least one level may comprise: querying a database to determine if there is an object below the feature of interest; and in the event there is no object below the feature of interest, moving the feature of interest down at least one level. The operation of optimizing for circuit edit may comprise moving the feature of interest to the bottom level. The operation of optimizing for circuit edit may comprise locating the feature of interest in close proximity with a second feature of interest. The operation of obtaining access to computer aided design data for an integrated circuit may comprise obtaining access to logic data and layout data for the integrated circuit. The operation of modifying the layout may comprise extending a net, the net associated with the layout. The operation of modifying the layout may comprise adding at least one via to a net to provide access to the net from a different layer, the net associated with the layout. The operation of modifying the layout may comprise changing a dimension of a net segment, the net segment associated with the layout. The operation of modifying the layout may comprise adding a gate. The operation of adding a gate comprises: obtaining a standard cell layout of the gate to be added; performing a spatial search of the layout to identify an insertion point; and inserting the standard cell layout at the insertion point.

According to further aspects of the invention, a computing platform is configured with computer executable instructions for performing the operations listed in the above paragraph.

According to yet further aspects of the invention, a method for an integrated circuit design for circuit edit is provided, comprising: receiving access to computer aided design data for an integrated circuit; receiving an identification of at least one feature of interest in the computer aided design data for a circuit edit operation; and determining whether a layout is optimized for the circuit edit operation, the layout associated with the computer aided design data.

According to further aspects of the invention, a method of optimizing an integrated circuit design is provided, comprising implementing physical structures into an integrated circuit design to promote post-fabrication editing and diagnosis. An integrated circuit is provided, which is designed according to the method described above.

### BRIEF DESCRIPTION OF THE DRAWINGS

The accompanying drawings, which are incorporated in, and constitute a part of, this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

The aspects of the present invention will become more apparent by describing in detail exemplary embodiments thereof with reference to the accompanying drawings, in which:

FIG. 1 is a flow chart depicting the method of optimizing the design of an integrated circuit according to one aspect of the present invention;

FIG. 2 is a flow chart illustrating the method of indicating a node of interest according to one aspect of the present invention;

FIG. 3 is a logic diagram illustrating the design of an integrated circuit according to one aspect of the present invention;

FIG. 4 is a logic diagram illustrating the design of an integrated circuit after a circuit edit process has been performed, according to one aspect of the present invention;

FIG. 5 is a flow chart depicting one part of the process of optimizing the design of an integrated circuit for circuit edit according to one aspect of the present invention;

FIG. 6 is a flow chart depicting the logic sequence for providing access to a net segment from a highest metal layer or a lowest metal layer, according to one aspect of the present invention;

FIG. 7 is a flow chart depicting one part of the process of moving a segment to a top-most metal layer to optimize the circuit edit operation, according to one aspect of the present invention;

FIG. 8 is a flow chart depicting the method of searching the net to determine if any new segments can be extended to provide access for a charged-particle beam tool; and

FIG. 9 is a flow chart illustrating the logic sequence used to optimize the addition of spare gates, transistors, and other functional structures to the integrated circuit layout.

### DETAILED DESCRIPTION

Aspects of the present invention involve a system and method for optimizing an integrated circuit design to account for post fabrication circuit editing. Implementations may involve adding design for edit (“DFE”) modifications and design for diagnostics (“DFD”) structures to an integrated circuit (“IC”) design, optimizing the IC design for charged particle beam tool (e.g., FIB tool, e-beam tool, etc. or other testing, editing, diagnostic and/or characterizing tools) processing and access to IC features, and optimizing the IC design for access to the DFE modifications and DFD structures. As used herein, “DFE” refers to modification of an integrated circuit design to provide adequate access to critical nodes, navigational references and other design changes that make circuit editing more efficient and reliable and otherwise optimize an IC design to account for possible future editing. The term “DFD” refers to integrated circuit design changes to include physical features such as spare metal lines, spare transistors, spare gates, and probe points for probing internal signals to enable rapid bug verification with a charged-particle beam tool and the like. A DFE or DFD-optimized IC may be used, for example, to improve manufacturing yields and to more quickly identify design and fabrication issues. DFE modifications and/or DFD structures may be accessed during a circuit operation, such as a circuit edit, probe point creation, or some other type of servicing operation using a charged-particle beam tool, laser circuit edit tool, or other type of circuit operation tool, to enable access to an internal signal, repair a defective circuit element, reroute a signal path, and the like.

Example DFE modifications may include, but are not limited to, properly sized pads and metal lines for probe points or net join operations and rerouting of metal lines for edit tool access. Example DFD structures may include, but are not limited to, spare gates, transistors, debug circuitry triggered or enabled at runtime and metal lines. During debug, a speed or timing failure may require measurement of internal signals to check for delays, rise and fall times, noise, etc. by accessing the appropriate probe points. Additionally, a speed path fix could require that a spare inverter gate or a spare metal line be inserted into the path to introduce additional delay or an inverter gate needs to be isolated or removed from a net.

In one sense, aspects of the invention involve optimizing an integrated circuit design for editing or debugging. Optimization of an IC for edit may involve, among other things, creating sufficient space between features so that a subsequent metal deposition by a charged particle beam tool to join two nets will generally satisfy design rules as well as DFE/DFD rules. Optimization of an IC for debug may involve, among other things, positioning a spare inverter gate in close proximity to a chain of inverters used as a delay line. In another sense, aspects of the invention involve determining optimal locations for DFE modifications of an IC or optimal positions for DFD structures so that the charged particle beam tool can be efficiently used to perform a potential circuit operation. This may involve providing access to a specific net, metal line, layer, etc., in the target IC design at a higher or the topmost metal layer for a front-side edit or at a lower or the lowest layer for a back-side edit. This may also involve the addition of navigation references so that features not visible from the surface can be rapidly and accurately located during a circuit edit. It may also involve creating access holes with lower aspect ratios (depth to diameter) to improve edit reliability and reduce edit time.

In one implementation, design for edit IC modification may be provided for three types of circuit operations: (1) net cutting, (2) net joining, and (3) probe point creation. As used herein, the term “circuit operation” is meant to refer to various possible operations, including circuit edits and probe point creation, that will be performed on a fabricated IC. The term “circuit edits” broadly refers to any type of charged particle beam, laser beam, or other procedure that modifies an IC in any way, including cutting or removing any feature of an integrated circuit as well as depositing material, such as depositing a conductor or trace to form an electrical connection or pathway. The term “probe point creation” broadly refers to any type of charged particle beam, laser beam, or other beam based procedure that creates an access point or connection to some feature, such as a metal line, via, or a contact, of an IC that facilitates obtaining information, such as waveforms, voltage levels, digital logic levels that may be compared to an expected result, etc., from the probed feature. In some instances, the term circuit edit is used synonymously with circuit operation and subsumes probe point creation.

DFD structures that may be added to an IC design include, but are not limited to, NAND gates, OR gates, inverters, metal lines, and probe points. Additionally, the layout may be optimized to provide efficient and reliable charged particle tool access to the structures.

DFE through optimization of net cutting involves providing adequate access to some portion of a given net to facilitate removal of some connectivity of the given net. DFE through optimization of net joining involves providing adequate access to certain portions of two or more nets to facilitate the joining of the two or more nets. Finally, DFE through optimization of probe point creation involves providing adequate access to the probe point to facilitate obtaining information from a net. As such, DFE optimization may involve an initial analysis to determine if there are any objects that would block direct access to the net or probe point by a FIB tool. In some implementations, additional analysis may be performed to determine if a net or probe point should be repositioned perhaps because other objects obstruct direct access. The repositioning may involve moving a portion of a net up one or more layers or down one or more layers. Other implementations may warrant further analysis involving design rule checks to determine if a net can be extended or otherwise repositioned.

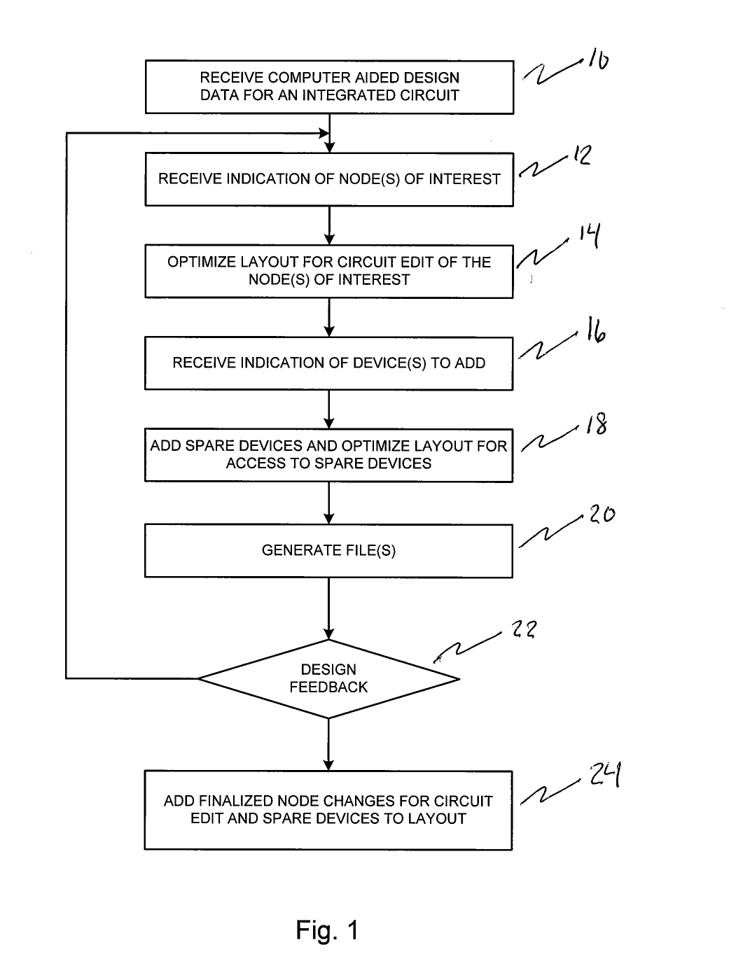

FIG. 1 is a flow chart diagram illustrating the operations associated with a method conforming to various aspects of the present invention. A circuit design engineer may access the computer aided design data for an integrated circuit (operation 10) that will be optimized for DFE and DFD using a computer-aided design workstation during, but not limited to, integrated circuit layout and floor planning. The designer typically has access to schematic diagrams of the integrated circuit as well as layout information detailing how signal paths are routed and how various devices are laid out. This information enables the designer to identify specific nodes that should be accessible and structures to be added to aid in the testing and debugging of a fabricated device using a particle beam tool or the like.

A circuit designer initially accesses CAD data for an IC design layout (operation 10) and indicates which nodes of the IC design should be made available for circuit operations (“nodes of interest”) (operation 12). The IC design information may be provided in LefDef, Oasis or GDS-II file format or databases like OpenAccess.

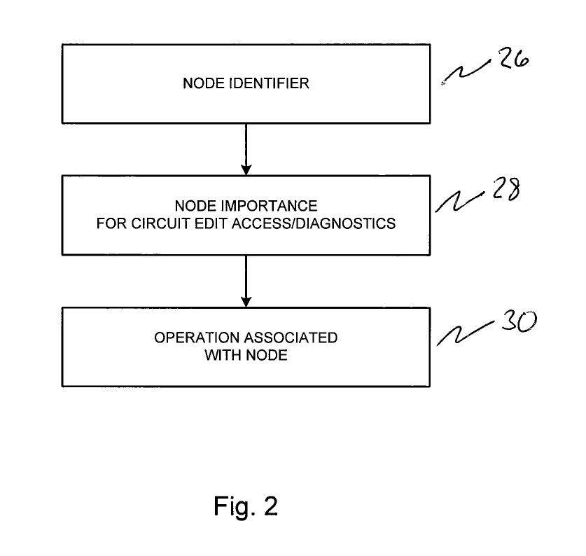

Referring to FIG. 2, in one particular implementation, an indication of a node of interest (from operation 12) generally includes a node identifier 26, an indication of node of importance for circuit edit access/diagnostics 28 and an operation associated with the node 30, such as net cut, net join or probe point creation. The node identifier 26 may include a net name, a net name at source or a gate/pin number. A net name may be used to specify a particular net or “wire” that connects devices together in an electronic design. A net name at source may be used to specify a specific location on a net. A gate/pin number may be used to specify a specific pin associated with a specific gate.

When the node identifier 26 is a net name, access to the net identified by the net name from any segment of the identified net will be optimized for the specified circuit edit operation (i.e., the net name is used to extract the polygons associated with the specified net to provide optimal access to a segment of the net for carrying out the circuit edit operation). When the node identifier 26 is a net name at source or gate/pin number, access to a particular segment (i.e., the polygon(s) of the net at the specified source location or the polygon(s) of the net connecting to the specified gate and pin number) of the associated net will be optimized for carrying out the circuit edit operation.

As used herein, the term “net” refers to an interconnection of metal lines at the same potential and carrying the same signal. The metal lines may be in one layer or may be located in different metal layers, and connected by way of vias or other connective structures. Such net information is generally contained in the netlist data of an IC layout. Netlist data can include a schematic diagram of various nets of the IC and also typically has polygon information illustrating the actual physical layout of the nets. Nets may interconnect cells at any level of hierarchy.

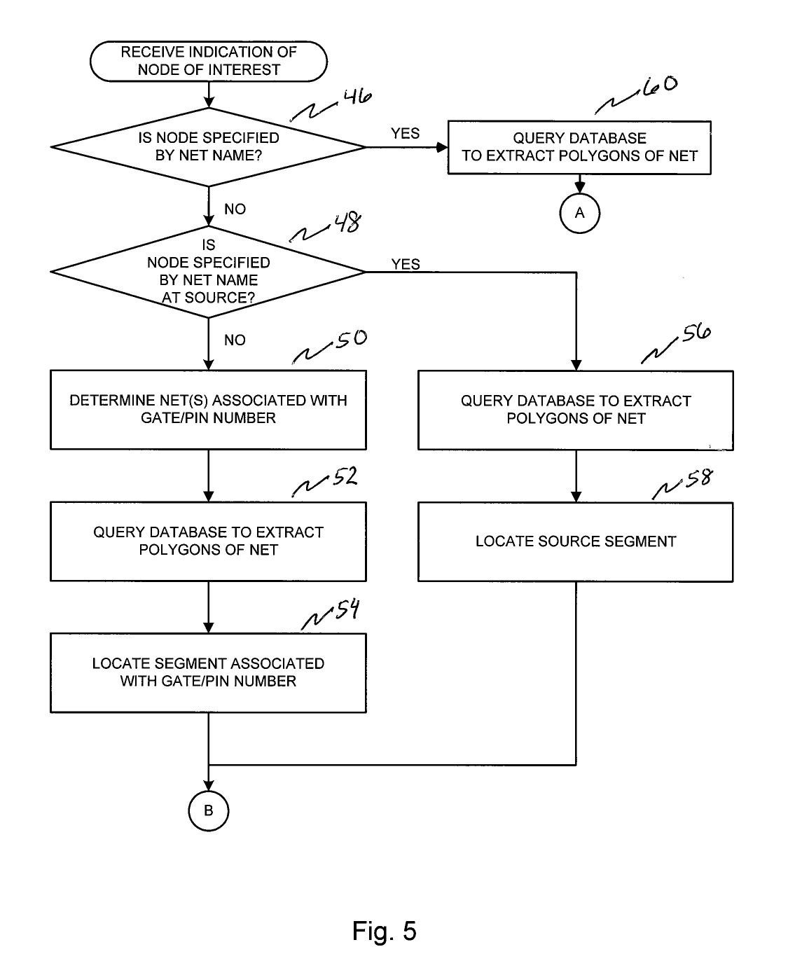

The IC layout may also be represented at the logic level using register transfer language (“RTL”) data. The RTL data can include a schematic representation illustrating various circuit elements, logical structures, and the like of the IC along with connections therebetween. The RTL data typically illustrates the logical connections between gates, logic elements, etc. Should the designer specify a connection to open, close, join, or probe at the logic level (see FIG. 1, operation 12), it can be translated to the corresponding net of the layout that is to be cut or probed, or the corresponding nets that are to be joined (see FIG. 5, operation 50 or operation 56).

Referring again to FIG. 2, some implementations may use the node importance for circuit edit access and diagnostics 28 to identify a critical node. As used herein the term “critical node” broadly refers to a node where circuit edit access should be provided because the node has a critical signal, a global signal or a unit level critical signal. For example, the designer may be pushing the design layout limits in certain areas. Circuit edit access to enable probing of particular node signals would be useful in isolating any timing related design issues. When a node is designated a critical node, the implementation may provide for notification to the designer when the layout cannot be modified to accommodate the requested circuit edit operation.

A designer also identifies a likely operation associated with the node of interest (operation 30). In one implementation the operation may be a net cut, a net join or a probe point creation. That is, the designer wants the layout modified in specific ways to aid in testing and debugging of the fabricated device. For example, when the designer specifies a net cut, the layout is modified to provide efficient and reliable access to the node of interest for a circuit edit net cut operation.

Referring again to FIG. 1, once the IC design information 10 and the nodes of interest 12 have been received, the IC design information, which generally includes layout data, is examined to determine the optimal points at which to perform a circuit operation (operation 14). During this operation, the design layout may be modified so that a charged particle beam tool can efficiently and reliably perform the circuit operation from the front-side or back-side. The design optimizations enable more efficient circuit edits that will not interfere with normal IC operation. In some embodiments of the present invention, when the desired circuit operation of a critical node cannot be inserted into the design without major design changes, that node is flagged and an alternative layout may be suggested to the designer. When required modifications are made to the existing layout (for example, to insert a probe point or a spare gate), the design rule checks and/or timing requirements might get disturbed or do not meet the specifications, an alternative layout might be suggested

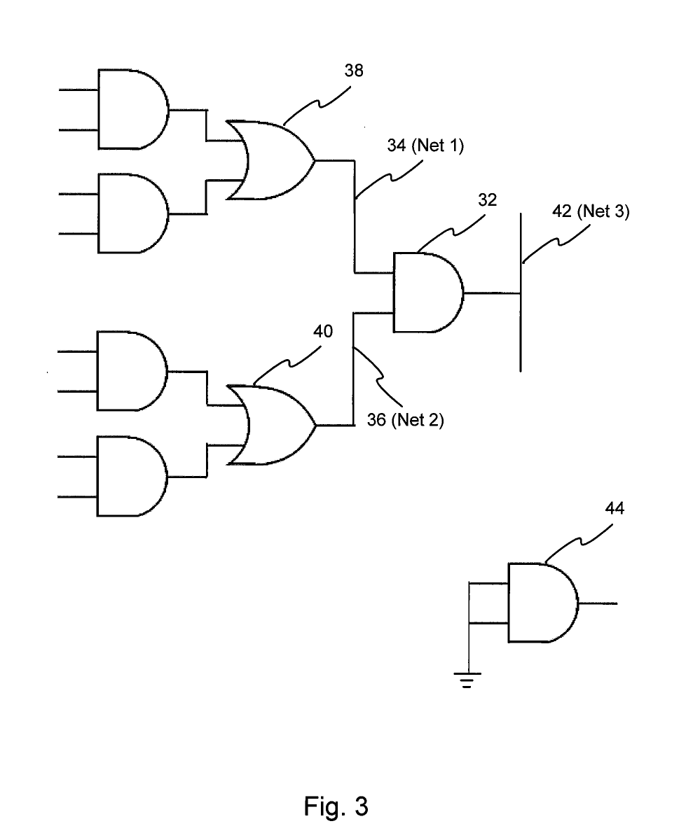

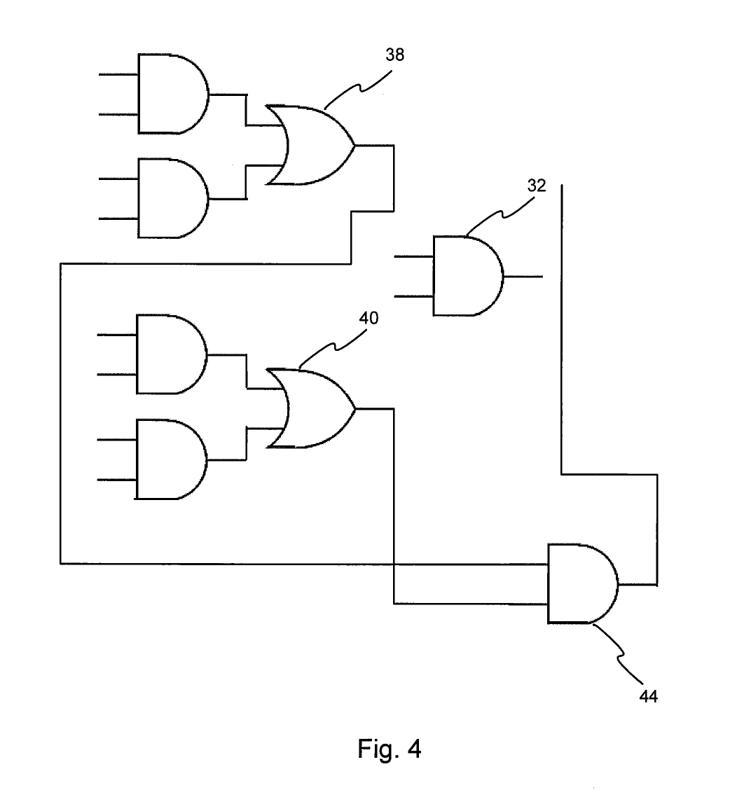

The designer may also indicate that spare gates or other functional structures should be added to the IC design (operation 16). As previously indicated, spare inverter gates and/or spare metal lines may be inserted into a signal path to add delay to fix a path speed error. Spare gates may also be added to fix a failure caused by a manufacturing yield problem. For example, FIG. 3 is an example of an RTL based logic diagram of a discrete section of an integrated circuit. The logic diagram includes an AND gate 32 with inputs (34,36) from two OR gates (38,40), and output 42 to other functional components. The connection 34 between the top OR gate 38 and the first input to the AND gate 32 corresponds to a first net (Net 1). The connection between the lower OR gate 40 and the second input 36 to the AND gate 32 corresponds to a second net (Net 2). Finally, the connection 42 from the AND gate to the other functional components corresponds to a third net (Net 3). During testing of the IC, it may be determined that the AND gate 32 is not functioning and thus it is desirable to replace the AND gate with another AND gate. In this example, a spare AND gate 44 is present in the lower right corner. The spare AND gate 44 is actually present in the fabricated circuit. FIG. 4 illustrates a logical rewiring that replaces the malfunctioning AND gate 32 with the spare AND gate 44. As such, the OR gates (38,40) are each connected to the appropriate input of the spare AND gate 44, and the output of the spare AND gate is connected to the other functional components.

In general, to disconnect the malfunctioning AND gate, the nets (34,36) associated with the AND gate inputs and the net 42 associated with the AND gate output will be cut in an appropriate location. Thus, nets 1 (34), 2 (36), and 3 (42) are cut, to isolate AND gate 32. These cuts will require precise navigation about the IC and precise employment of a focused ion beam to mill a hole in the IC to the appropriate vertical and horizontal location to sever some portion of the appropriate nets. Further, to connect the spare AND gate 44, various nets will be electrically connected. The FIB will be employed to cut trenches and deposit conductor between the nets associated with each OR gate output 38, 40 and the nets of the respective inputs of the spare AND gate 44, and to deposit conductor between the net of the spare AND gate output and the net 3 (42) associated with the other functional components. Such FIB operations are made easier if adequate access to the appropriate nets through intervening layers has been provided, navigation reference points have been provided, and the spare AND gate 44 has been located in close proximity to the malfunctioning AND gate 32. Some implementations may allow for addition of a DFD structure and subsequently optimize the layout (DFE) for access to the DFD structure and other structures.

In one implementation, the functional structures to be added may be specified as standard cells. In other implementations, a database may be queried to extract the details of the functional structures to be added. Once the detailed information of the structure has been obtained, the layout may be spatially searched to find a location where each gate can be added. Priority may be given to locations that are less densely occupied than other possible locations. Priority may also be given to locations that are less densely populated on upper metal layers, so that access to the structure is made easier. Access to the pins of added gates may be made available on the topmost metal layer to minimize circuit edits should the gate later be used during debug of the fabricated device. The size of the structure to be inserted is taken into consideration. The layout is scanned to see where this structure can be placed either in normal form or in a rotated orientation. If multiple locations are detected then priority is given to the one which is less densely populated on the upper metal layers, I.e., priority is given to locations having easier accessibility.

The information generated by one embodiment may also include one or more files containing information for performing the circuit operations added during the DFE/DFD process with a charged particle beam tool or other circuit operation tool. Examples of charged particle beam tools that may make use of these files include the Credence Systems Corporation's IDS OptiFIB focused ion beam tool (Credence Systems Corporation, Milpitas, Calif.), which includes an ion column coaxially aligned with an optical microscope. The OptiFIB system can direct a focused ion beam on a target IC for circuit edits and probe point creation, and can also obtain optical images of the IC as well as secondary electron based images.

Referring again to FIG. 1, in one implementation of the present invention, after the design has been optimized for DFE and/or DFD, one or more truncated GDS-II files with circuit operation information and other layout information are generated (operation 20). It is also possible to generate truncated LefDef, Oasis, or other layout file types. The truncated GDS-II file includes layout information for each DFE/DFD feature and layout information in the immediate surrounding area, but eliminates other layout information. As such, the truncated GDS-II file is dramatically smaller in size than a complete GDS-II file for the entire IC. The truncated GDS-II file is thus more wieldy and smaller in size making transmission of it over a network quicker and requiring less memory. GDS-II files are typically highly proprietary, and many companies do not allow or heavily restrict usage within their own company, let alone permit vendor access to GDS-II files. A truncated GDS-II file provided in implementations of the present invention ameliorates this potential issue in that the truncated GDS-II file is very incomplete with respect to the entire target IC layout, but is highly complete with respect to target circuit operation locations of the target IC. As such, a truncated GDS-II file may be communicated to vendors and provide accurate circuit operation information, but not provide much other information associated with the layout of the target IC.

Once the design has been optimized for DFE and DFD, the designer can access the truncated design layout file to verify the details of each proposed DFE modification and/or DFD structure, including layout and location, and may accept or reject them (operation 22). Further, if access to a critical node cannot be provided, the designer may modify the layout to provide circuit edit access and other optimizations for the critical node. Or, the designer may decide to designate an alternative node as a node of interest. If additional nodes of interest are specified, the process may be repeated to optimize the layout for the additional nodes.

Finally, once the designer is satisfied with the proposed DFE modifications and DFD structures, including layouts and locations, they may be incorporated into the layout (operation 24). Once the layout has been optimized for circuit edit and DFD, the design process is complete.

The following description involves one example of an implementation of a system and method for adding DFE modifications and DFD structures to an existing IC layout. Any particular implementation may involve only a subset of the overall implementation set forth herein. Moreover, any possible implementation may take advantage of the inventive concepts set forth herein, but may take on a different form of implementation than specifically set forth herein. The description involves reference to the high level block diagram of FIG. 1 and the flowcharts of FIGS. 5-9 illustrating one possible arrangement of operations.

Referring again to FIG. 1, the design layout information received (operation 10) by one embodiment of the present invention may include whether the layout is for an analog or digital IC, the gate length of the process technology (e.g., 90 nanometer, 0.18 micrometer, etc.) used to fabricate the IC, the number of aluminum and copper metal layers, the total number of layers, whether a dummy layer is provided and at what level, and whether the IC is a wire bonded or flip-chip device.

FIGS. 5-8 depict flowcharts of the logic used by one embodiment of the invention to optimize a design of an integrated circuit for DFE and DFD, such as described with respect to operation 14 of FIG. 1. As previously discussed, this may involve modifying the design and/or adding structures to the design. Later operations depend on how the node of interest is specified in operation 12. A node may be specified by net name, net name at the source, or by a pin number of a gate. Referring to FIG. 5, checks are performed to determine the node identifier type (operations 46,48). In operation 46, if the node identifier type is net name, then a database containing the layout information may be queried to extract the polygons of the specified net (operation 60). In this instance, the entire net identified by the net name may be examined to determine an optimal point for the DFE operation as further described below.

In operation 48, if the node is specified by net name at the source, then the database may be queried to extract the polygons of the specified net (operation 56). Then, the list of polygons of the net is examined to identify the net segment that corresponds with the specified net name at source (operation 58). In this instance, a specific segment of a net has been specified and the net is examined starting with the specified segment to determine if the specified segment or a nearby segment can be optimized for the DFE operation as further described below.

In operation 48, if the node is specified by a gate/pin number, then the database may be queried to determine the net associated with the pin of the specified gate (operation 50). Next, the database is further queried to extract the polygons of the net (operation 52) and to locate the segment of the net associated with the specified gate/pin number (operation 54). Again, in this instance, a specific segment of a net that corresponds (i.e., is in close proximity) to the specified gate/pin number has been specified. The net is examined starting with the specified segment to determine if the specified segment or a nearby segment can be optimized for the DFE operation as further described below.

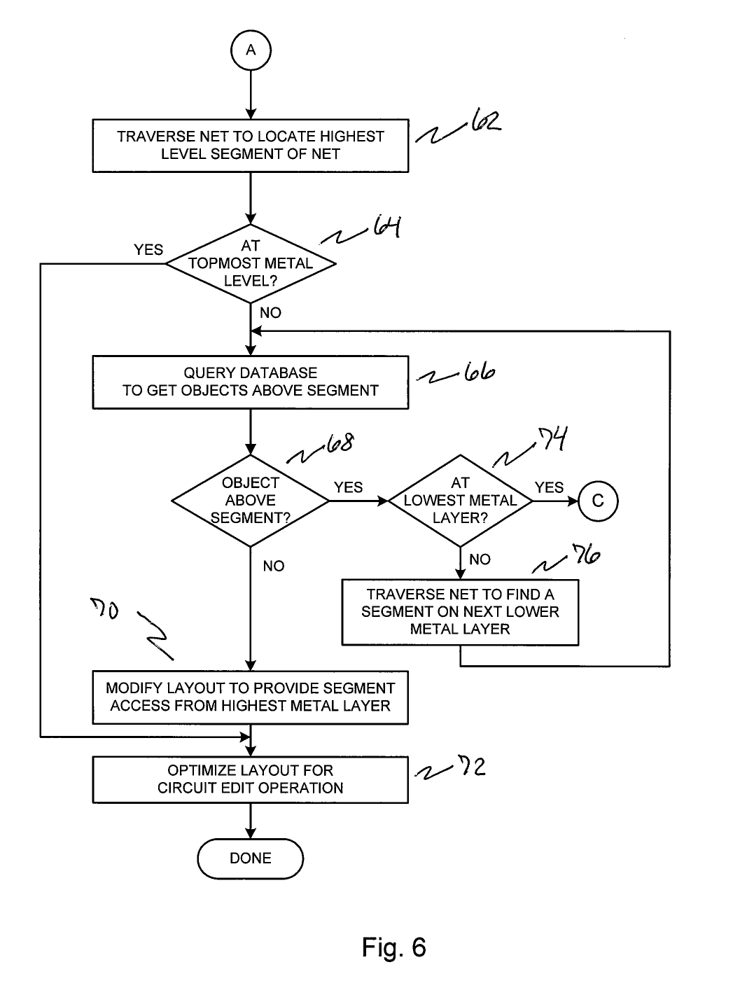

Once the net associated with the node of interest has been determined, the segments that make up the net are generally examined starting with those segments located on the highest metal layer associated with the net to determine if access to that segment from the topmost metal layer is possible. If access is not possible from these segments, then segments located on successively lower metal layers are analyzed. Referring now to FIG. 6, after the database has been queried to extract the polygons of a node specified by net name (see FIG. 5, operation 60), the net may be traversed to locate a segment at the highest metal layer associated with the net (operation 62). The net is comprised of polygons. Each polygon has a metal layer associated with it. These polygons may be stored in a list. Each polygon is then inspected, starting with the polygon on the top-most metal layer. The search ends when an accessible polygon is found (i.e. there is no polygon of a different net above it). Once this segment has been located, a check may be performed to determine if the segment is located on the topmost metal layer (operation 64). If the segment is located on the topmost metal layer, then the layout may be optimized for the circuit edit operation (operation 72). Some implementations may optimize the layout by, among other things, adding a properly sized pad for a probe point or a net join.

Referring back to operation 64, if the highest level segment of the net is not on the topmost metal layer, a database may be queried to determine whether any objects are located above the segment (operation 66). If there are any objects above the segment (operation 68), the process proceeds to operation 74. If there are no objects above the segment, then the design may be modified to provide access to the segment from the topmost metal layer (operation 70). Access for a net join circuit edit may be accomplished by adding a via from the segment to the topmost metal layer along with a pad. Access for a net cut may be accomplished by adding two vias from the current segment to the topmost metal layer so that a portion of the segment can be relocated to the topmost layer. Access for a probe point may be accomplished by adding a via from the segment to the topmost metal layer and adding a probe point pad on the topmost metal layer. Other implementations of the present invention may move a segment to a higher metal layer if not moving the segment results in an access hole aspect ratio that would cause the edit operation to be more difficult, too time consuming, or less reliable.

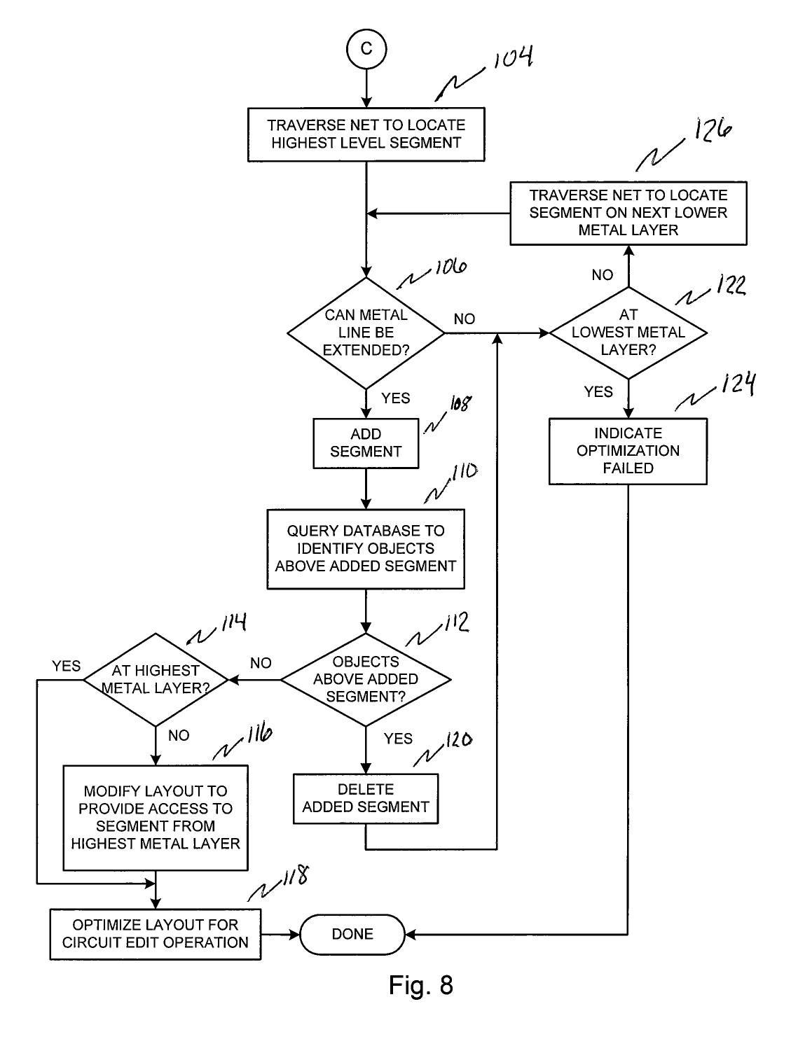

Referring back to operation 68, if there is an object above the segment, then a check is performed to determine if the segment is located on the lowest metal layer associated with the net (operation 74). If the segment is not on the lowest layer of the net, then the net is traversed to find a segment on the next lower layer (operation 76). This lower segment is then examined to determine if it can be brought up to the topmost metal layer (operations 66, 68). Referring back to operation 74, if the segment is on the lowest layer of the net, then the net has been traversed and no segments have been found not blocked by other objects. Then, the net is examined to determine if any segments can be extended to provide access from the topmost metal layer as further described in FIG. 8. In some embodiments of the present invention, access from the lowest metal layer, rather than the highest metal layer, may be provided to facilitate back-side edits. Other embodiments may search the net to locate any other segments on a given layer to determine if any of those segments can be brought to the desired topmost metal layer (or bottom most layer for a back-side edit).

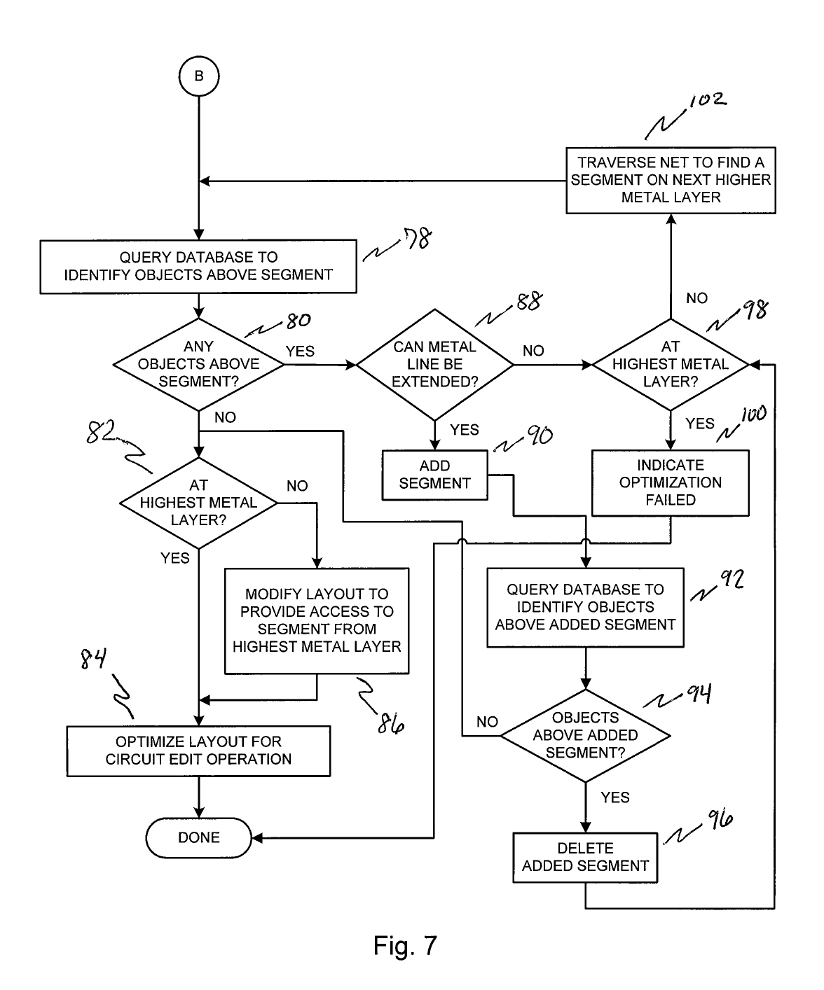

Referring now to FIG. 7, after the segment associated with a node specified by net name at the source or by gate/pin number has been identified, the database may be queried to determine if any objects are located above the segment (operation 78). If there are any objects above the segment (operation 80), the process proceeds to step 88. If there are no objects above the segment, then a check is performed to determine if the segment is at the topmost metal layer (operation 82). If the segment is located at the topmost metal layer, then the layout may be optimized for the circuit edit operation (operation 84). Referring back to operation 82, if the segment is not at the topmost metal layer, then the design layout may be modified to provide access to the segment from the topmost metal layer (operation 86). Then, operation 84 is performed. Note that Operation 84 is skipped if the segment is at highest level, at which point the process is completed. On the other hand, if its not at the highest level, we provide access to it at the highest level then try to optimize the layout because some design elements may need new placement.

Referring back to operation 80, if there are objects above the segment, a check is performed to determine if the metal line associated with the segment can be extended (operation 88). In some implementations this may involve determining whether the metal line can be extended horizontally or vertically, depending on the metal layer, without interfering with another metal line on that layer. If the metal line can be extended, a segment is added to extend the metal line (operation 90). Next, the database may be queried to identify any objects above the added segment (operation 92). If there are any objects above the added segment (operation 94), the process proceeds to step 96. If there are no objects above the added segment, operation 82 is executed.

Referring back to operation 94, if there are objects above the added segment, then the added segment is deleted (operation 96). Then, a check is performed to determine if the segment is located on the topmost metal layer of the net (operation 98). If it is on the topmost layer, then optimization of the layout for the circuit edit operation for the specified node was not successful (operation 100). That is, access to the object cannot be achieved by extending a metal line, since attempted addition of a segment line still resulted in a segment line having an object above it, and the object is already at the highest metal line, so cannot traverse higher.

Referring back to operation 98, if the segment is not on the highest metal layer of the net, then the net is traversed to find a segment located on the next higher layer (operation 102). Then, various method steps beginning with operation 78 are executed.

Referring back to operation 88, if the metal line cannot be extended, then operation 98 is executed.

Referring now to FIG. 8, in the event that all segments of a net specified by net name are blocked by other objects, the net may be searched to determine if any segments can be extended to provide access. The operations to determine if any segment of the net can be extended are very similar to the operations for extending a segment as described with respect to FIG. 7, with the addition of an option to traverse a lower metal layer instead of an upper metal layer. This operation would benefit an integrated circuit designed for back-side edit. First, the net is traversed to locate the highest level segment (operation 104). Then, a check is performed to determine if the metal line associated with the segment can be extended (operation 106). If the metal line can be extended, a segment is added to extend the metal line (operation 108). Next, the database may be queried to identify any objects above the added segment (operation 110). A check is then performed to determine if there are any objects above the added segment (operation 112). If there are no objects above the added segment, operation 114 is executed to determine if the segment is at the topmost metal layer. If the segment is located at the topmost metal layer, then the layout may be optimized for the circuit edit operation (operation 118). Referring back to operation 114, if the segment is not at the topmost metal layer, then the design layout may be modified to provide access to the segment from the topmost metal layer (operation 116). Then, operation 118 is performed to optimize the layout.

Referring back to operation 112, if there are objects above the added segment, then the added segment is deleted (operation 120). Then, a check is performed to determine if the segment is located on the lowest metal layer of the net (operation 122). If it is on the lowest layer, then optimization of the layout for the circuit edit operation for the specified node was not successful (operation 124).

Referring back to operation 122, if the segment is not on the lowest metal layer of the net, then the net is traversed to find a segment located on the next lowest metal layer (operation 126).

As previously discussed, some embodiments of the present invention, may optimize access from the lowest metal layer, rather than the topmost metal layer, to facilitate back-side edits. Other embodiments may check all the segments located on a given layer to determine if any of them can be brought to the desired topmost metal layer (or bottom most layer for a back-side edit) before checking for segments located on other metal layers.

For backside edits the design for edit must take into account the locations of active elements that were fabricated in the substrate, such as transistors, trench capacitors, etc. Notably, the issue here is not that metal line may be in the way, but rather the active elements may be in the way of reaching a certain metal line. So, the design for edits needs to optimize access to metal lines in between active elements fabricated in the substrate.

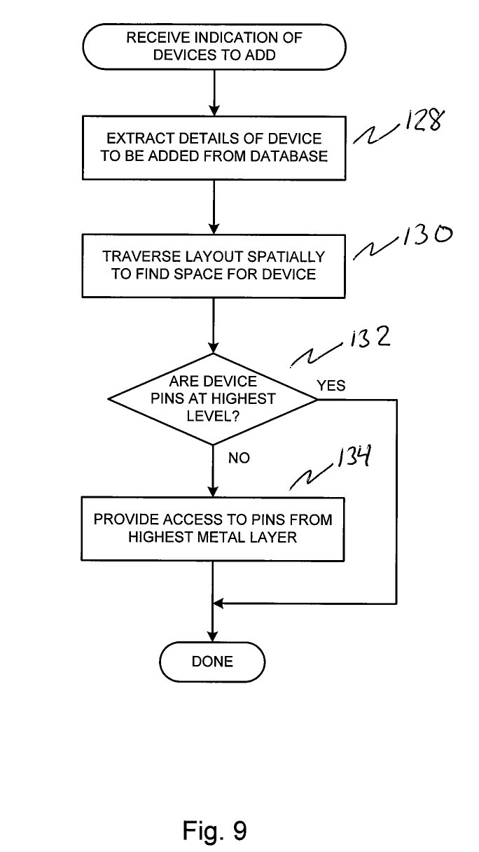

FIG. 9 illustrates the logic to optimize the addition of spare gates, transistors and other functional structures to the integrated circuit layout (FIG. 1, operation 18). Once an indication of a device to add has been received (see FIG. 1, operation 16), the layout related details of the device are extracted (operation 128). In some implementations this may involve extracting the bounding box for the device design from the standard cell description for the device. Once the bounding box has been obtained, the layout is traversed spatially to find an optimum place to add the device (operation 130). Optimal placement may include, in one embodiment, giving priority to locations that are less densely populated than other locations, giving priority to locations where device pins are on higher or lower metal layers, etc.

A check is then performed to determine if the device pins are located on the highest metal layer (or lowest, in other back-side edit implementations) (operation 132). If they are not on the desired layer, access to the pins from the desired layer may be provided (operation 134). The logic to do this is similar to the previously described logic for providing access to a net segment from the highest or lowest metal layer (see FIG. 6).

The various specific operations described above may be deployed in a single computing platform, or more likely a plurality of computing platforms configured to communicate over private and/or public networks.

For optimal probe point generation, the system implements or may access a method and apparatus for determining optimal probe point placement. In one example, the apparatus and method for determining optimal probe point placement is described in U.S. Pat. No. 5,675,499 titled “Optimal Probe Point Placement,” issued on Oct. 7, 1997 (hereinafter the '499 patent), which is hereby incorporated by reference herein. For optimal net cutting and net connection location generation, the system incorporates or may access an apparatus and method for determining optimal cutting and joining operations. In one implementation, the system employs or may access an apparatus and method for optimal location of a net cut or a net joining as disclosed in U.S. patent application Ser. No. 10/257,034 (U.S. Pub. No. 2003/0079187) titled “Method and Device for Automatic Optimal Location of an Operation on an Integrated Circuit,” filed on Apr. 6, 2001, and published on Apr. 24, 2003 (hereinafter the '034 application), the disclosure of which is hereby incorporated by reference herein.

For optimal probe point placement, the system consults the layout description and netlist description along with cross-reference descriptions of the target IC. The system compares layout information concerning each net with various probe point placement rules in order to locate a possible probe point. In one implementation, the application generates more than one possible probe point location and also provides a rating or score associated with each possible probe point. The '499 patent referenced above provides additional details concerning the rules associated with determining and rating possible probe points. The optimal probe point placement patent also includes information concerning ways to identify optimal net cutting locations and net joining locations. The '034 application describes a method for determining optimal locations for an operation on an integrated circuit. As with the '499 patent, the '034 application describes an apparatus and method that analyzes layout and net listing information in order to generate a list of optimal locations to perform a net cut or net joining operation. Again, a list of possible net cut or net joining locations are generated along with a rating for each possible operation.

Referring again to FIG. 1, upon optimization of the layout for all or part of the DFE modifications and/or DFD structures, one or more files may be generated, such as a truncated layout file and an encrypted file which may include circuit node location information, navigation reference information, beam characteristics and other aspects of the circuit operations (operation 24).

Various aspects of the present invention, whether alone or in combination with other aspects of the invention, may be implemented in C++ code running on a computing platform operating in a LSB 2.0 Linux environment. However, aspects of the invention provided herein may be implemented in other programming languages adapted to operate in other operating system environments. Further, methodologies may be implemented in any type of computing platform, including but not limited to, personal computers, mini-computers, main-frames, workstations, networked or distributed computing environments, computer platforms separate, integral to, or in communication with charged particle tools, and the like. Further, aspects of the present invention may be implemented in machine readable code provided in any memory medium, whether removable or integral to the computing platform, such as a hard disc, optical read and/or write storage mediums, RAM, ROM, and the like. Moreover, machine readable code, or portions thereof, may be transmitted over a wired or wireless network.

Although various representative embodiments of this invention have been described above with a certain degree of particularity, those skilled in the art could make numerous alterations to the disclosed embodiments without departing from the spirit or scope of the inventive subject matter set forth in the specification and claims. In methodologies directly or indirectly set forth herein, various steps and operations are described in one possible order of operation, but those skilled in the art will recognize that steps and operations may be rearranged, replaced, or eliminated without necessarily departing from the spirit and scope of the present invention. It is intended that all matter contained in the above description or shown in the accompanying drawings shall be interpreted as illustrative only and not limiting.

What is claimed is:

1. A method for an integrated circuit design for circuit edit comprising:
receiving access to computer aided design data for an integrated circuit;
receiving an identification of at least one feature of interest in the computer aided design data for a circuit edit operation; and
providing a layout modification to optimize the circuit edit operation, the layout modification associated with the computer aided design data.

2. The method of claim 1, further comprising selecting the feature of interest from the group consisting of a net, metal line, layer, contact, and via.

3. The method of claim 1, further comprising selecting the circuit edit operation from the group consisting of net cut, net join, probe point, and gate replacement.

4. The method of claim 1 wherein the operation of optimizing for circuit edit comprises moving the feature of interest up at least one level.

5. The method of claim 4, wherein the operation of moving the feature of interest up at least one level further comprises:
querying a database to determine if there is an object above the feature of interest; and
in the event there is no object above the feature of interest, moving the feature of interest up at least one level.

6. The method of claim 1, further comprising moving the feature of interest to the top level.

7. The method of claim 1 wherein the operation of optimizing for circuit edit comprises moving the feature of interest down at least one level.

8. The method of claim 7 wherein the operation of moving the feature of interest down at least one level comprises:
querying a database to determine if there is an object below the feature of interest; and
in the event there is no object below the feature of interest, moving the feature of interest down at least one level.

9. The method of claim 1 wherein the operation of optimizing for circuit edit comprises moving the feature of interest to the bottom level.

10. The method of claim 1 wherein the operation of optimizing for circuit edit comprises locating the feature of interest in close proximity with a second feature of interest.

11. The method of claim 1 wherein the operation of obtaining access to computer aided design data for an integrated circuit comprises obtaining access to logic data and layout data for the integrated circuit.

12. The method of claim 1 wherein the operation of modifying the layout comprises extending a net, the net associated with the layout.

13. The method of claim 1 wherein the operation of modifying the layout comprises adding at least one via to a net to provide access to the net from a different layer, the net associated with the layout.

14. The method of claim 1 wherein the operation of modifying the layout comprises changing a dimension of a net segment, the net segment associated with the layout.

15. The method of claim 1 wherein the operation of modifying the layout comprises adding a gate.

16. The method of claim 15 wherein the operation of adding a gate comprises:
obtaining a standard cell layout of the gate to be added;
performing a spatial search of the layout to identify an insertion point; and
inserting the standard cell layout at the insertion point.

17. A computing platform configured with computer executable instructions for performing the operations of claim 1.

18. A method for an integrated circuit design for circuit edit comprising:
receiving access to computer aided design data for an integrated circuit;
receiving an identification of at least one feature of interest in the computer aided design data for a circuit edit operation; and
determining whether a layout is optimized for the circuit edit operation, the layout associated with the computer aided design data.

19. A method of optimizing an integrated circuit design comprising implementing physical structures into an integrated circuit design to promote post-fabrication editing and diagnosis.

20. An integrated circuit designed according to the method of claim 1.
